(19) United States
(12) Patent Application Publication
(10) Pub. No.: US 2026/0269825 A1
(43) Pub. Date: Sep. 10, 2026

(54) SEMICONDUCTOR CHIP AND METHOD FOR TESTING THE SAME

(71) Applicant: TAIWAN SEMICONDUCTOR MANUFACTURING COMPANY, LTD., Hsinchu (TW)

(72) Inventors: CHUN TING YANG, Hsinchu (TW); Wei-Chen LEE, Hsinchu (TW); Ping-Hsiang HUANG, Hsinchu (TW); Chu Fu CHEN, Hsinchu (TW)

(73) Assignee: TAIWAN SEMICONDUCTOR MANUFACTURING COMPANY, LTD., Hsinchu (TW)

(21) Appl. No.: 19/069,394

(22) Filed: Mar. 4, 2025

(51) Int. Cl. H03K 17/687; G01R 31/26

(52) U.S. Cl. CPC H03K 17/687; G01R 31/2621

(57) ABSTRACT

A semiconductor chip is to be powered by a first supply voltage and a second supply voltage. The first supply voltage is larger than the second supply voltage in magnitude. The semiconductor chip includes a p-type field effect transistor (FET) and a gate driver. A source/drain region of the p-type FET is to receive the first supply voltage. The gate driver is connected to the gate electrode of the p-type FET, and is configured to generate a gate drive signal for receipt by the gate electrode of the p-type FET. The gate drive signal switches between a high voltage level and a low voltage level. The low voltage level corresponds to conduction of the p-type FET, and is smaller than a magnitude of the first supply voltage. The high voltage level corresponds to non-conduction of the p-type FET, and is larger than the magnitude of the first supply voltage.

### BACKGROUND

Before the mass production stage of semiconductor chip fabrication, a chip probe (CP) test (i.e., a yield test) and a high temperature operating life (HTOL) test (i.e., a reliability test) are sequentially performed on the semiconductor chips, so as to find the semiconductor chips that have defects. However, during the mass production stage, only the chip probe test may be performed to find out which semiconductor chips have defects. Therefore, it is better to find the semiconductor chips with defects in the chip probe test rather than in the high temperature operating life test.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating a method for testing a semiconductor chip in accordance with some embodiments.

FIG. 2 is a circuit diagram illustrating a semiconductor chip in accordance with some embodiments.

FIG. 3 is a circuit diagram illustrating a semiconductor chip in accordance with some embodiments.

FIG. 4 is a schematic diagram illustrating a semiconductor chip in accordance with some embodiments.

FIG. 5 is a plot illustrating a first leakage current distribution of the semiconductor chip of FIG. 4 in accordance with some embodiments.

FIG. 6 is a plot illustrating a second leakage current distribution of the semiconductor chip of FIG. 4 in accordance with some embodiments.

FIG. 7 is a circuit block diagram illustrating a semiconductor chip in accordance with some embodiments.

FIG. 8 is a circuit diagram illustrating a condition where a p-type field effect transistor of the semiconductor chip of FIG. 7 is tested in accordance with some embodiments.

FIG. 9 is a circuit diagram illustrating a condition where an n-type field effect transistor of the semiconductor chip of FIG. 7 is tested in accordance with some embodiments.

FIG. 10 is a circuit block diagram illustrating a semiconductor chip in accordance with some embodiments.

FIG. 11 is a circuit block diagram illustrating a semiconductor chip in accordance with some embodiments.

FIG. 12 is a circuit block diagram illustrating a semiconductor chip in accordance with some embodiments.

FIG. 13 is a circuit block diagram illustrating a semiconductor chip in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

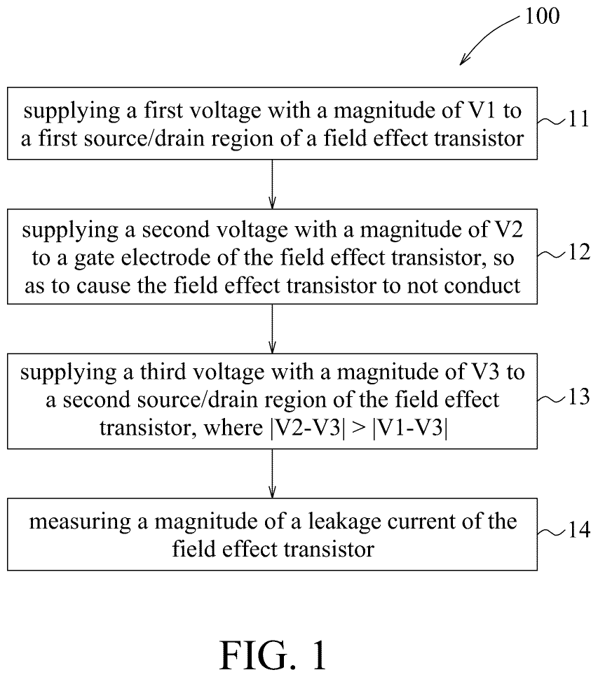

FIG. 1 is a flow chart illustrating a method 100 for testing a semiconductor chip in accordance with some embodiments. Referring to FIG. 1, the method 100 is performed on the semiconductor chip to detect a leakage current of a field effect transistor (FET) of the semiconductor chip, and includes steps 11-14. The field effect transistor has a gate electrode, a first source/drain region and a second source/drain region, and includes a plurality of transistor devices that are connected to each other in parallel so as to be able to provide a current with a large magnitude. In some embodiments, the field effect transistor may be a power field effect transistor, or any other suitable type of field effect transistor. In step 11, a first voltage with a magnitude of V1 is supplied to the first source/drain region of the field effect transistor. In step 12, a second voltage with a magnitude of V2 is supplied to the gate electrode of the field effect transistor, so as to cause the field effect transistor to not conduct. In step 13, a third voltage with a magnitude of V3 is supplied to the second source/drain region of the field effect transistor. A magnitude difference between the second voltage and the third voltage is larger than a magnitude difference between the first voltage and the third voltage (i.e., |V2−V3|>|V1−V3|). In step 14, a magnitude of the leakage current of the field effect transistor is measured.

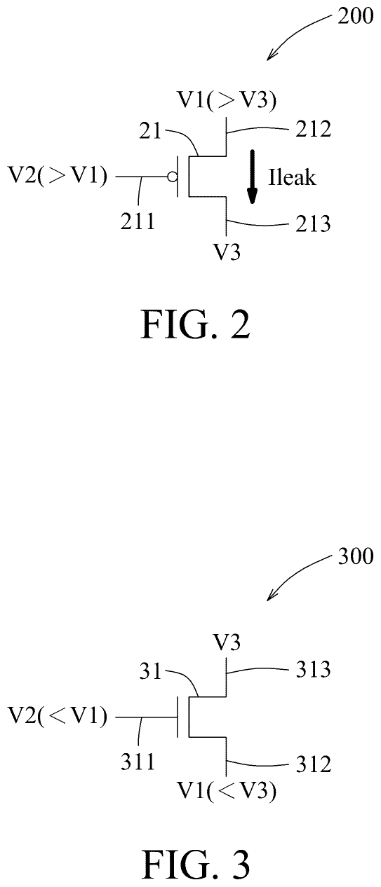

FIG. 2 is a circuit diagram illustrating a semiconductor chip 200 in accordance with some embodiments. Referring to FIGS. 1 and 2, the semiconductor chip 200 only includes a p-type field effect transistor 21. The p-type field effect transistor 21 has a gate electrode 211, a first source/drain region 212 and a second source/drain region 213, and includes a plurality of transistor devices (not shown) that are connected to each other in parallel so as to be able to provide a current with a large magnitude. The method 100 can be performed on the semiconductor chip 200 to detect a leakage current of the p-type field effect transistor 21, with a magnitude (V1) of the first voltage larger than a magnitude (V3) of the third voltage (i.e., V1>V3) and a magnitude (V2) of the second voltage larger than the magnitude (V1) of the first voltage (i.e., V2>V1). Therefore, as compared to a condition where the first voltage, instead of the second voltage, is supplied to the gate electrode 211 of the p-type field effect transistor 21, a magnitude difference (V2−V1) between the first voltage and the second voltage is expected to reduce a magnitude (Ileak) of the leakage current of the p-type field effect transistor 21 (i.e., the magnitude (Ileak) of the leakage current of the p-type field effect transistor 21 would be reduced as expected if the p-type field effect transistor 21 does not have any defects, and may not be reduced significantly if the p-type field effect transistor 21 has defects). In some embodiments, the magnitude difference (V2−V1) between the first voltage and the second voltage may fall within a range of from about 0.2×Vt to about 5×Vt (i.e., 0.2×Vt<V2−V1<5×Vt), where Vt denotes an absolute value of a threshold voltage of the p-type field effect transistor 21. In some embodiments, the magnitude difference (V2−V1) between the first voltage and the second voltage may fall within a range of from about 0.2×Vt to about 4×Vt (i.e., 0.2×Vt<V2−V1<4×Vt). In some embodiments, the magnitude difference (V2−V1) between the first voltage and the second voltage may fall within a range of from about 0.2×Vt to about 3×Vt (i.e., 0.2×Vt<V2−V1<3×Vt). In some embodiments, the magnitude difference (V2−V1) between the first voltage and the second voltage may fall within a range of from about 0.2×Vt to about 2×Vt (i.e., 0.2×Vt<V2−V1<2×Vt). In some embodiments, the magnitude difference (V2−V1) between the first voltage and the second voltage may fall within a range of from about 0.2×Vt to about 1×Vt (i.e., 0.2×Vt<V2−V1<1×Vt). In some embodiments, the magnitude difference (V2−V1) between the first voltage and the second voltage may reduce the magnitude (Ileak) of the leakage current of the p-type field effect transistor 21 by at least about ten times (i.e., about an order) and at most about a thousand times (i.e., about three orders). When the magnitude difference (V2−V1) between the first voltage and the second voltage is smaller than about 0.2×Vt (i.e., V2−V1<0.2×Vt), the expected reduction of the magnitude (Ileak) of the leakage current of the p-type field effect transistor 21 may not be significant. When the magnitude difference (V2−V1) between the first voltage and the second voltage is larger than about 1×Vt (i.e., V2−V1>1×Vt), a gate induced drain leakage (GIDL) may occur to result in an increase of the magnitude (Ileak) of the leakage current of the p-type field effect transistor 21.

FIG. 3 is a circuit diagram illustrating a semiconductor chip 300 in accordance with some embodiments. Referring to FIGS. 1 and 3, the semiconductor chip 300 only includes an n-type field effect transistor 31. The n-type field effect transistor 31 has a gate electrode 311, a first source/drain region 312 and a second source/drain region 313, and includes a plurality of transistor devices (not shown) that are connected to each other in parallel so as to be able to provide a current with a large magnitude. The method 100 can be performed on the semiconductor chip 300 to detect a leakage current of the n-type field effect transistor 31, with the magnitude (V1) of the first voltage smaller than the magnitude (V3) of the third voltage (i.e., V1<V3) and the magnitude (V2) of the second voltage smaller than the magnitude (V1) of the first voltage (i.e., V2<V1). Therefore, as compared to a condition where the first voltage, instead of the second voltage, is supplied to the gate electrode 311 of the n-type field effect transistor 31, a magnitude difference (V1−V2) between the first voltage and the second voltage is expected to reduce a magnitude (Ileak) of the leakage current of the n-type field effect transistor 31 (i.e., the magnitude (Ileak) of the leakage current of the n-type field effect transistor 31 would be reduced as expected if the n-type field effect transistor 31 does not have any defects, and may not be reduced significantly if the n-type field effect transistor 31 has defects). In some embodiments, the magnitude difference (V1−V2) between the first voltage and the second voltage may fall within a range of from about 0.2×Vt to about 5×Vt (i.e., 0.2×Vt<V1−V2<5×Vt), where Vt denotes a magnitude of a threshold voltage of the n-type field effect transistor 31. In some embodiments, the magnitude difference (V1−V2) between the first voltage and the second voltage may fall within a range of from about 0.2×Vt to about 4×Vt (i.e., 0.2×Vt<V1−V2<4×Vt). In some embodiments, the magnitude difference (V1−V2) between the first voltage and the second voltage may fall within a range of from about 0.2×Vt to about 3×Vt (i.e., 0.2×Vt<V1−V2<3×Vt). In some embodiments, the magnitude difference (V1−V2) between the first voltage and the second voltage may fall within a range of from about 0.2×Vt to about 2×Vt (i.e., 0.2×Vt<V1−V2<2×Vt). In some embodiments, the magnitude difference (V1−V2) between the first voltage and the second voltage may fall within a range of from about 0.2×Vt to about 1×Vt (i.e., 0.2×Vt<V1−V2<1×Vt). In some embodiments, the magnitude difference (V1−V2) between the first voltage and the second voltage may reduce the magnitude (Ileak) of the leakage current of the n-type field effect transistor 31 by at least about ten times (i.e., about an order) and at most about a thousand times (i.e., about three orders). When the magnitude difference (V1−V2) between the first voltage and the second voltage is smaller than about 0.2×Vt (i.e., V1−V2<0.2×Vt), the expected reduction of the magnitude (Ileak) of the leakage current of the n-type field effect transistor 31 may not be significant. When the magnitude difference (V1−V2) between the first voltage and the second voltage is larger than about 1×Vt (i.e., V1−V2>1×Vt), a gate induced drain leakage (GIDL) may occur which results in an increase of the magnitude (Ileak) of the leakage current of the n-type field effect transistor 31.

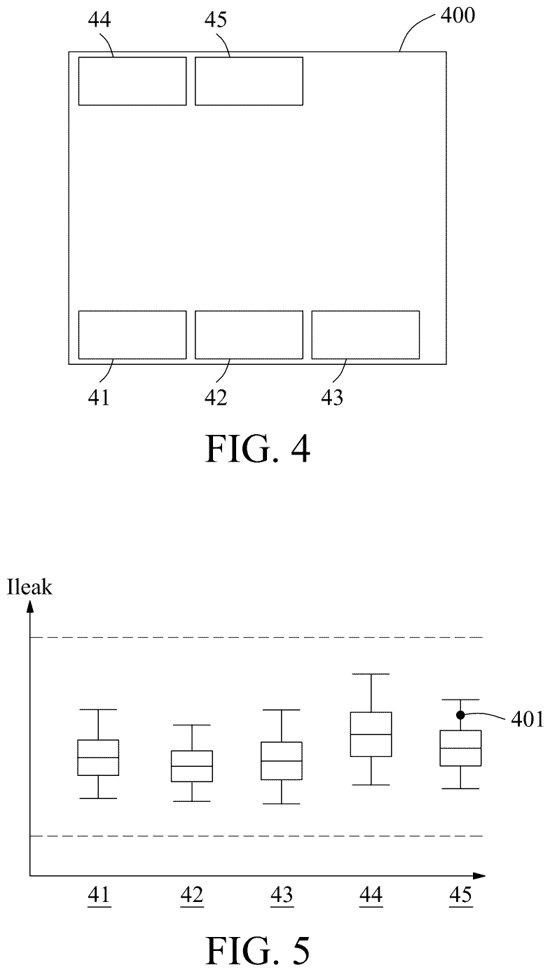

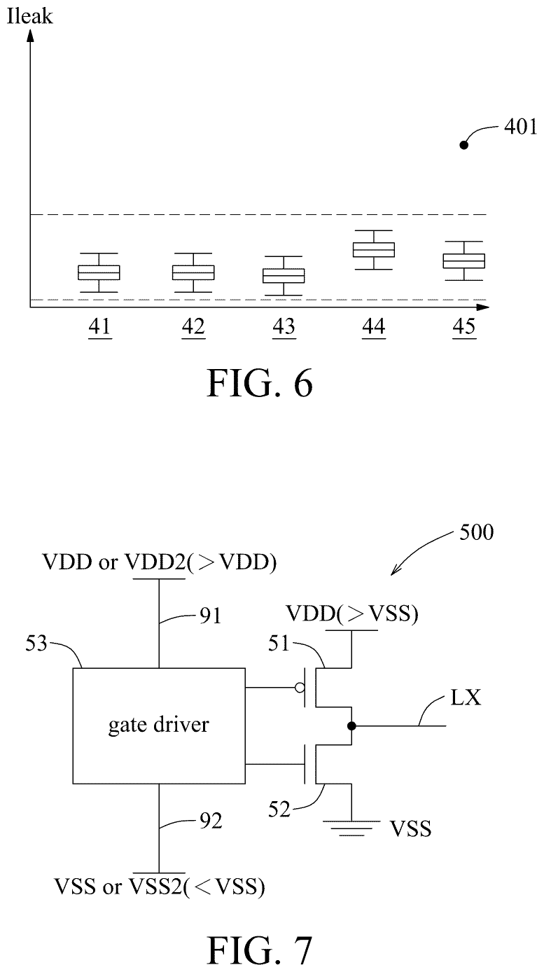

FIG. 4 is a schematic diagram illustrating a semiconductor chip 400 in accordance with some embodiments. FIG. 5 is a plot illustrating a first leakage current distribution of the semiconductor chip 400 of FIG. 4 in accordance with some embodiments. FIG. 6 is a plot illustrating a second leakage current distribution of the semiconductor chip 400 of FIG. 4 in accordance with some embodiments. Referring to FIGS. 1 and 4 to 6, the semiconductor chip 400 includes a first field effect transistor 41, a second field effect transistor 42, a third field effect transistor 43, a fourth field effect transistor 44 and a fifth field effect transistor 45. Each of the field effect transistors 41-45 is identical to one of the p-type field effect transistor 21 depicted in FIG. 2 and the n-type field effect transistor 31 depicted in FIG. 3. When a plurality of the semiconductor chips 400 are tested in a condition where the gate electrode, the first source/drain region and the second source/drain region of each of the field effect transistors 41-45 of the semiconductor chips 400 are respectively supplied with the first voltage, the first voltage and the third voltage, a distribution of magnitudes (Ileak) of leakage currents of the field effect transistors 41-45 of the semiconductor chips 400 are shown in FIG. 5. When the semiconductor chips 400 are tested using the method 100 (i.e., the gate electrode, the first source/drain region and the second source/drain region of each of the field effect transistors 41-45 of the semiconductor chips 400 are respectively supplied with the second voltage, the first voltage and the third voltage), a distribution of the magnitudes (Ileak) of the leakage currents of the field effect transistors 41-45 of the semiconductor chips 400 are shown in FIG. 6. With respect to each of the field effect transistors 41-45 of the semiconductor chips 400, if the field effect transistor does not have any defects, the magnitude (Ileak) of the leakage current of the field effect transistor would be significantly reduced when the corresponding semiconductor chip 400 is tested using the method 100, and if the field effect transistor has one or more tiny defects (e.g., the fifth field effect transistor 45 that corresponds to the point 401), the magnitude (Ileak) of the leakage current of the field effect transistor would not be significantly reduced when the corresponding semiconductor chip 400 is tested using the method 100. Therefore, by virtue of performing the method 100 on the semiconductor chips 400, defects in the semiconductor chip 400 that includes the fifth field effect transistor 45 corresponding to the point 401 can be found out based on the magnitude (Ileak) of the leakage current of the fifth field effect transistor 45 corresponding to the point 401. It should be noted that the method 100 can be executed in the chip probe (CP) test to find out which ones of the semiconductor chips 400 that have tiny defects, thereby enhancing the quality and the delivery time of the semiconductor chips 400.

FIG. 7 is a circuit block diagram illustrating a semiconductor chip 500 in accordance with some embodiments. Referring to FIG. 7, the semiconductor chip 500 is to be powered by a first supply voltage and a second supply voltage, and optionally by a third supply voltage and a fourth supply voltage. The first supply voltage, the second supply voltage, the third supply voltage and the fourth supply voltage are provided by at least one power source (not shown) that is external to the semiconductor chip 500. A magnitude (VDD) of the first supply voltage is larger than a magnitude (VSS) of the second supply voltage (i.e., VDD>VSS). A magnitude (VDD2) of the third supply voltage is larger than the magnitude (VDD) of the first supply voltage (i.e., VDD2>VDD). A magnitude (VSS2) of the fourth supply voltage is smaller than the magnitude (VSS) of the second supply voltage (i.e., VSS2<VSS). The semiconductor chip 500 includes a p-type field effect transistor 51, an n-type field effect transistor 52 and a gate driver 53. The p-type field effect transistor 51 is identical to the p-type field effect transistor 21 depicted in FIG. 2. The n-type field effect transistor 52 is identical to the n-type field effect transistor 31 depicted in FIG. 3. The first source/drain region of the p-type field effect transistor 51 receives the first supply voltage. The first source/drain region of the n-type field effect transistor 52 receives the second supply voltage. The second source/drain region of the p-type field effect transistor 51 and the second source/drain region of the n-type field effect transistor 52 are connected to each other. The gate driver 53 is connected to the at least one power source through two power lines 91, 92 (the power line 91 is for transmitting the first supply voltage and the third supply voltage, and the power line 92 is for transmitting the second supply voltage and the fourth supply voltage), and is to be powered by the first supply voltage and the second supply voltage (i.e., the at least one power source provides the first supply voltage and the second supply voltage to the gate driver 53 through the power lines 91, 92) or powered by the third supply voltage and the fourth supply voltage (i.e., the at least one power source provides the third supply voltage and the fourth supply voltage to the gate driver 53 through the power lines 91, 92). The gate driver 53 is further connected to the gate electrode of the p-type field effect transistor 51 and the gate electrode of the n-type field effect transistor 52, and is configured to generate a first gate drive signal that is to be received by the gate electrode of the p-type field effect transistor 51 and a second gate drive signal that is to be received by the gate electrode of the n-type field effect transistor 52. Each of the first gate drive signal and the second gate drive signal switches between a high voltage level and a low voltage level. The first gate drive signal would cause the p-type field effect transistor 51 to not conduct when at the high voltage level, and would cause the p-type field effect transistor 51 to conduct when at the low voltage level. The second gate drive signal would cause the n-type field effect transistor 52 to conduct when at the high voltage level, and would cause the n-type field effect transistor 52 to not conduct when at the low voltage level. When the gate driver 53 is powered by the first supply voltage and the second supply voltage, the high voltage level is equal to the magnitude (VDD) of the first supply voltage, and the low voltage level is equal to the magnitude (VSS) of the second supply voltage. When the gate driver 53 is powered by the third supply voltage and the fourth supply voltage, the high voltage level is equal to the magnitude (VDD2) of the third supply voltage, and the low voltage level is equal to the magnitude (VSS2) of the fourth supply voltage. It should be noted that, in normal operation of the semiconductor chip 500, the gate driver 53 is powered by the first supply voltage and the second supply voltage.

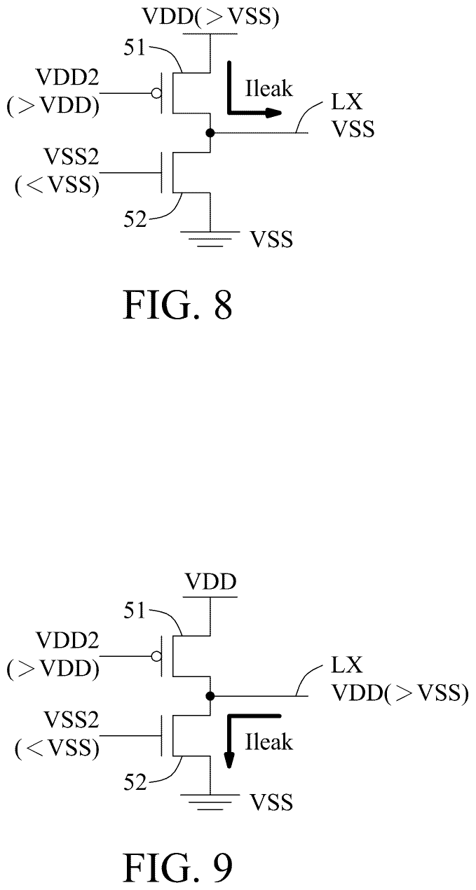

FIG. 8 is a circuit diagram illustrating a condition where the p-type field effect transistor 51 of the semiconductor chip 500 of FIG. 7 is tested in accordance with some embodiments. Referring to FIGS. 1, 7 and 8, the method 100 can be performed on the semiconductor chip 500 to detect a leakage current of the p-type field effect transistor 51. Specifically, in step 11, the first supply voltage with the magnitude (VDD) is supplied to the first source/drain region of the p-type field effect transistor 51 to serve as the first voltage. In step 12, the third supply voltage with the magnitude (VDD2) and the fourth supply voltage with the magnitude (VSS2) are supplied to the gate driver 53, and the gate driver 53 is controlled to output, to the gate electrode of the p-type field effect transistor 51, the first gate drive signal that is at the high voltage level equal to the magnitude (VDD2) of the third supply voltage to serve as the second voltage, so as to cause the p-type field effect transistor 51 to not conduct. In step 13, the second supply voltage with the magnitude (VSS) is supplied to a common node (LX) of the p-type field effect transistor 51 and the n-type field effect transistor 52 to serve as the third voltage. In step 14, a meter (not shown) is connected to the common node (LX) of the p-type field effect transistor 51 and the n-type field effect transistor 52, and measures a magnitude (Ileak) of the leakage current of the p-type field effect transistor 51. It should be noted that, while the method 100 is performed on the semiconductor chip 500 to detect the leakage current of the p-type field effect transistor 51, the second supply voltage with the magnitude (VSS) is supplied to the first source/drain region of the n-type field effect transistor 52, so a voltage magnitude difference between the first source/drain region and the second source/drain region of the n-type field effect transistor 52 is zero, no current flows through the n-type field effect transistor 52, and the current magnitude measured at the common node (LX) of the p-type field effect transistor 51 and the n-type field effect transistor 52 is equal to the magnitude (Ileak) of the leakage current of the p-type field effect transistor 51. It should also be noted that, in some embodiments, while the method 100 is performed on the semiconductor chip 500 to detect the leakage current of the p-type field effect transistor 51, the gate driver 53 may be controlled to output, to the gate electrode of the n-type field effect transistor 52, the second gate drive signal that is at the low voltage level equal to the magnitude (VSS2) of the fourth supply voltage, so as to cause the n-type field effect transistor 52 to not conduct.

FIG. 9 is a circuit diagram illustrating a condition where the n-type field effect transistor 52 of the semiconductor chip 500 of FIG. 7 is tested in accordance with some embodiments. Referring to FIGS. 1, 7 and 9, the method 100 can be performed on the semiconductor chip 500 to detect a leakage current of the n-type field effect transistor 52. Specifically, in step 11, the second supply voltage with the magnitude (VSS) is supplied to the first source/drain region of the n-type field effect transistor 52 to serve as the first voltage. In step 12, the third supply voltage with the magnitude (VDD2) and the fourth supply voltage with the magnitude (VSS2) are supplied to the gate driver 53, and the gate driver 53 is controlled to output, to the gate electrode of the n-type field effect transistor 52, the second gate drive signal that is at the low voltage level equal to the magnitude (VSS2) of the fourth supply voltage to serve as the second voltage, so as to cause the n-type field effect transistor 52 to not conduct. In step 13, the first supply voltage with the magnitude (VDD) is supplied to the common node (LX) of the p-type field effect transistor 51 and the n-type field effect transistor 52 to serve as the third voltage. In step 14, a meter (not shown) is connected to the common node (LX) of the p-type field effect transistor 51 and the n-type field effect transistor 52, and measures a magnitude (Ileak) of the leakage current of the n-type field effect transistor 52. It should be noted that, while the method 100 is performed on the semiconductor chip 500 to detect the leakage current of the n-type field effect transistor 52, the first supply voltage with the magnitude (VDD) is supplied to the first source/drain region of the p-type field effect transistor 51, so a voltage magnitude difference between the first source/drain region and the second source/drain region of the p-type field effect transistor 51 is zero, no current flows through the p-type field effect transistor 51, and the current magnitude measured at the common node (LX) of the p-type field effect transistor 51 and the n-type field effect transistor 52 is equal to the magnitude (Ileak) of the leakage current of the n-type field effect transistor 52. It should also be noted that, in some embodiments, while the method 100 is performed on the semiconductor chip 500 to detect the leakage current of the n-type field effect transistor 52, the gate driver 53 may be controlled to output, to the gate electrode of the p-type field effect transistor 51, the first gate drive signal that is at the high voltage level equal to the magnitude (VDD2) of the third supply voltage, so as to cause the p-type field effect transistor 51 to not conduct.

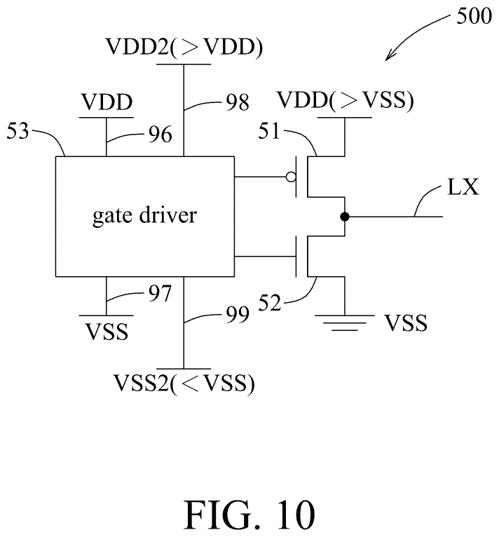

FIG. 10 is a circuit block diagram illustrating a semiconductor chip 500 in accordance with some embodiments. The semiconductor chip 500 depicted in FIG. 10 is similar to the semiconductor chip 500 depicted in FIG. 7, but differs from the semiconductor chip 500 depicted in FIG. 7 in that the gate driver 53 is connected to the at least one power source through four power lines 96-99 (the power line 96 is for transmitting the first supply voltage, the power line 97 is for transmitting the second supply voltage, the power line 98 is for transmitting the third supply voltage, and the power line 99 is for transmitting the fourth supply voltage), and is to be powered by the first supply voltage and the second supply voltage (i.e., the at least one power source provides the first supply voltage and the second supply voltage to the gate driver 53 through the power lines 96, 97, and does not provide the third supply voltage and the fourth supply voltage) or powered by the third supply voltage and the fourth supply voltage (i.e., the at least one power source provides the third supply voltage and the fourth supply voltage to the gate driver 53 through the power lines 98, 99, and does not provide the first supply voltage and the second supply voltage).

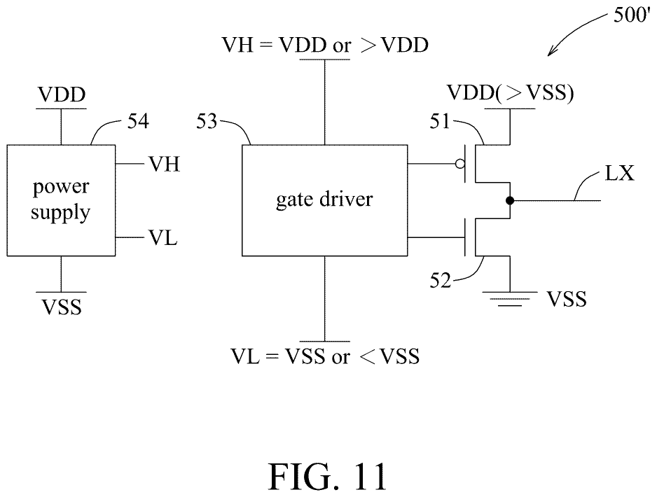

FIG. 11 is a circuit block diagram illustrating a semiconductor chip 500′ in accordance with some embodiments. Referring to FIGS. 1 and 11, the semiconductor chip 500′ is similar to the semiconductor chip 500 depicted in FIG. 7, but differs from the semiconductor chip 500 depicted in FIG. 7 in that: (a) the semiconductor chip 500′ is not powered by the third supply voltage and the fourth supply voltage that are provided by the power source external to the semiconductor chip 500′; (b) the semiconductor chip 500′ further includes a power supply 54; and (c) the semiconductor chip 500′ is operable in a normal mode and a test mode. The power supply 54 is to be powered by the first supply voltage with the magnitude (VDD) and the second supply voltage with the magnitude (VSS), is connected to the gate driver 53, and is configured to supply a high supply voltage and a low supply voltage to power the gate driver 53. When the semiconductor chip 500′ operates in the normal mode, a magnitude (VH) of the high supply voltage is equal to the magnitude (VDD) of the first supply voltage, and a magnitude (VL) of the low supply voltage is equal to the magnitude (VSS) of the second supply voltage. When the semiconductor chip 500′ operates in the test mode, the magnitude (VH) of the high supply voltage is larger than the magnitude (VDD) of the first supply voltage, and the magnitude (VL) of the low supply voltage is smaller than the magnitude (VSS) of the second supply voltage. In some embodiments, the power supply 54 may use a charge pump circuit or any other suitable circuit to cause the magnitude (VH) of the high supply voltage to be larger than the magnitude (VDD) of the first supply voltage, and to cause the magnitude (VL) of the low supply voltage to be smaller than the magnitude (VSS) of the second supply voltage. When the method 100 is performed on the semiconductor chip 500′ to detect a leakage current of the p-type field effect transistor 51, in step 12, the semiconductor chip 500′ is set to operate in the test mode, so the gate driver 53 outputs, to the gate electrode of the p-type field effect transistor 51, the first gate drive signal that is at the high voltage level larger than the magnitude (VDD) of the first supply voltage to serve as the second voltage, so as to cause the p-type field effect transistor 51 to not conduct. When the method 100 is performed on the semiconductor chip 500′ to detect a leakage current of the n-type field effect transistor 52, in step 12, the semiconductor chip 500′ is set to operate in the test mode, so the gate driver 53 outputs, to the gate electrode of the n-type field effect transistor 52, the second gate drive signal that is at the low voltage level smaller than the magnitude (VSS) of the second supply voltage to serve as the second voltage, so as to cause the n-type field effect transistor 52 to not conduct.

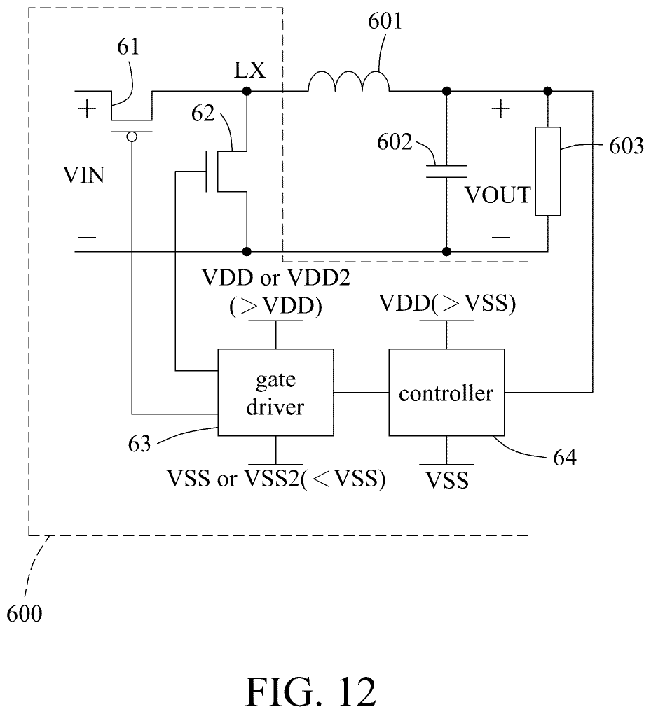

FIG. 12 is a circuit block diagram illustrating a semiconductor chip 600 in accordance with some embodiments. Referring to FIG. 12, the semiconductor chip 600 is to be powered by a first supply voltage and a second supply voltage, and optionally by a third supply voltage and a fourth supply voltage. The first supply voltage, the second supply voltage, the third supply voltage and the fourth supply voltage are provided by a power source (not shown) that is external to the semiconductor chip 600. A magnitude (VDD) of the first supply voltage is larger than a magnitude (VSS) of the second supply voltage (i.e., VDD>VSS). A magnitude (VDD2) of the third supply voltage is larger than the magnitude (VDD) of the first supply voltage (i.e., VDD2>VDD). A magnitude (VSS2) of the fourth supply voltage is smaller than the magnitude (VSS) of the second supply voltage (i.e., VSS2<VSS). The semiconductor chip 600 includes a p-type field effect transistor 61, an n-type field effect transistor 62, a gate driver 63 and a controller 64, and cooperates with an inductor 601 and a capacitor 602 to form a buck converter that converts an input voltage into an output voltage for powering a load 603. A magnitude (VOUT) of the output voltage is smaller than a magnitude (VIN) of the input voltage. The p-type field effect transistor 61 is identical to the p-type field effect transistor 21 depicted in FIG. 2. The n-type field effect transistor 62 is identical to the n-type field effect transistor 31 depicted in FIG. 3. The first source/drain region of the p-type field effect transistor 61 and the first source/drain region of the n-type field effect transistor 62 cooperatively receive the input voltage. The second source/drain region of the p-type field effect transistor 61 and the second source/drain region of the n-type field effect transistor 62 are connected to each other. The gate driver 63 is to be powered by the first supply voltage and the second supply voltage, or by the third supply voltage and the fourth supply voltage. The gate driver 63 is connected to the gate electrode of the p-type field effect transistor 61 and the gate electrode of the n-type field effect transistor 62, and is configured to generate, based on a control input, a first gate drive signal that is to be received by the gate electrode of the p-type field effect transistor 61 and a second gate drive signal that is to be received by the gate electrode of the n-type field effect transistor 62. Each of the first gate drive signal and the second gate drive signal switches between a high voltage level and a low voltage level. The first gate drive signal would cause the p-type field effect transistor 61 to not conduct when at the high voltage level, and would cause the p-type field effect transistor 61 to conduct when at the low voltage level. The second gate drive signal would cause the n-type field effect transistor 62 to conduct when at the high voltage level, and would cause the n-type field effect transistor 62 to not conduct when at the low voltage level. The first gate drive signal and the second gate drive signal would not cause the p-type field effect transistor 61 and the n-type field effect transistor 62 to conduct simultaneously. When the gate driver 63 is powered by the first supply voltage and the second supply voltage, the high voltage level is equal to the magnitude (VDD) of the first supply voltage, and the low voltage level is equal to the magnitude (VSS) of the second supply voltage. When the gate driver 63 is powered by the third supply voltage and the fourth supply voltage, the high voltage level is equal to the magnitude (VDD2) of the third supply voltage, and the low voltage level is equal to the magnitude (VSS2) of the fourth supply voltage. It should be noted that, in normal operation of the semiconductor chip 600, the gate driver 63 is powered by the first supply voltage and the second supply voltage. A first terminal of the inductor 601 is connected to a common node (LX) of the p-type field effect transistor 61 and the n-type field effect transistor 62. A first terminal of the capacitor 602 is connected to a second terminal of the inductor 601. A second terminal of the capacitor 602 is connected to the first source/drain region of the n-type field effect transistor 62. The load 603 is connected to the capacitor 602 in parallel. A voltage across the capacitor 602 serves as the output voltage. The controller 64 is to be powered by the first supply voltage and the second supply voltage, and is connected to the gate driver 63 and the capacitor 602. The controller 64 is configured to perform pulse width modulation (PWM) or pulse frequency modulation (PFM) based on the output voltage so as to generate the control input that is to be received by the gate driver 63, thereby stabilizing the magnitude (VOUT) of the output voltage. The method 100 depicted in FIG. 1 can be performed on the semiconductor 600 to detect a leakage current of the p-type field effect transistor 61 in the way depicted in FIG. 8. The method 100 depicted in FIG. 1 can be performed on the semiconductor 600 to detect a leakage current of the n-type field effect transistor 62 in the way depicted in FIG. 9.

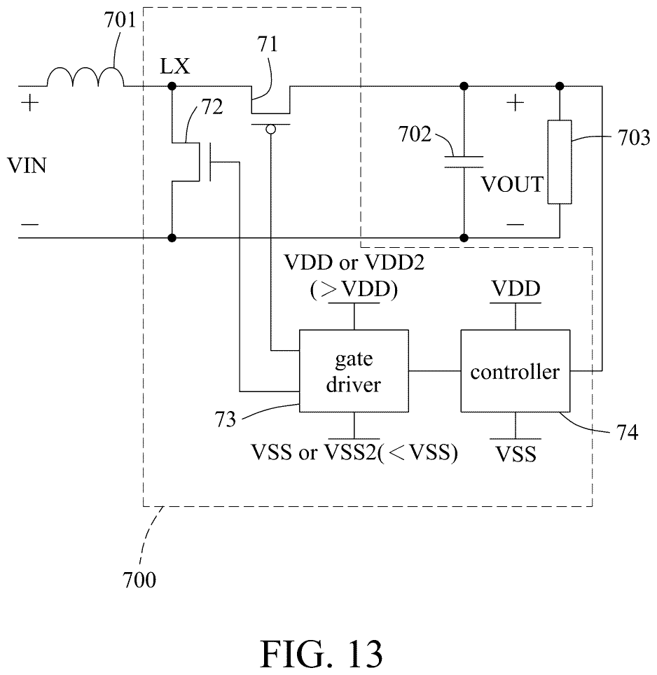

FIG. 13 is a circuit block diagram illustrating a semiconductor chip 700 in accordance with some embodiments. Referring to FIG. 13, the semiconductor chip 700 is to be powered by a first supply voltage and a second supply voltage, and optionally by a third supply voltage and a fourth supply voltage. The first supply voltage, the second supply voltage, the third supply voltage and the fourth supply voltage are provided by a power source (not shown) that is external to the semiconductor chip 700. A magnitude (VDD) of the first supply voltage is larger than a magnitude (VSS) of the second supply voltage (i.e., VDD>VSS). A magnitude (VDD2) of the third supply voltage is larger than the magnitude (VDD) of the first supply voltage (i.e., VDD2>VDD). A magnitude (VSS2) of the fourth supply voltage is smaller than the magnitude (VSS) of the second supply voltage (i.e., VSS2<VSS). The semiconductor chip 700 includes a p-type field effect transistor 71, an n-type field effect transistor 72, a gate driver 73 and a controller 74, and cooperates with an inductor 701 and a capacitor 702 to form a boost converter that converts an input voltage into an output voltage for powering a load 703. A magnitude (VOUT) of the output voltage is larger than a magnitude (VIN) of the input voltage. The p-type field effect transistor 71 is identical to the p-type field effect transistor 21 depicted in FIG. 2. The n-type field effect transistor 72 is identical to the n-type field effect transistor 31 depicted in FIG. 3. The first source/drain region of the p-type field effect transistor 71 is connected to a first terminal of the capacitor 702. The first source/drain region of the n-type field effect transistor 72 is connected to a second terminal of the capacitor 702. The second source/drain region of the p-type field effect transistor 71 and the second source/drain region of the n-type field effect transistor 72 are connected to each other. A common node (LX) of the p-type field effect transistor 71 and the n-type field effect transistor 72 is connected to a first terminal of the inductor 701. A second terminal of the inductor 701 and the first source/drain region of the n-type field effect transistor 72 cooperatively receive the input voltage. The gate driver 73 is to be powered by the first supply voltage and the second supply voltage, or by the third supply voltage and the fourth supply voltage. The gate driver 73 is connected to the gate electrode of the p-type field effect transistor 71 and the gate electrode of the n-type field effect transistor 72, and is configured to generate, based on a control input, a first gate drive signal that is to be received by the gate electrode of the p-type field effect transistor 71 and a second gate drive signal that is to be received by the gate electrode of the n-type field effect transistor 72. Each of the first gate drive signal and the second gate drive signal switches between a high voltage level and a low voltage level. The first gate drive signal would cause the p-type field effect transistor 71 to not conduct when at the high voltage level, and would cause the p-type field effect transistor 71 to conduct when at the low voltage level. The second gate drive signal would cause the n-type field effect transistor 72 to conduct when at the high voltage level, and would cause the n-type field effect transistor 72 to not conduct when at the low voltage level. The first gate drive signal and the second gate drive signal would not cause the p-type field effect transistor 71 and the n-type field effect transistor 72 to conduct simultaneously. When the gate driver 73 is powered by the first supply voltage and the second supply voltage, the high voltage level is equal to the magnitude (VDD) of the first supply voltage, and the low voltage level is equal to the magnitude (VSS) of the second supply voltage. When the gate driver 73 is powered by the third supply voltage and the fourth supply voltage, the high voltage level is equal to the magnitude (VDD2) of the third supply voltage, and the low voltage level is equal to the magnitude (VSS2) of the fourth supply voltage. It should be noted that, in normal operation of the semiconductor chip 700, the gate driver 73 is powered by the first supply voltage and the second supply voltage. The load 703 is connected to the capacitor 702 in parallel. A voltage across the capacitor 702 serves as the output voltage. The controller 74 is to be powered by the first supply voltage and the second supply voltage, and is connected to the gate driver 73 and the capacitor 702. The controller 74 is configured to perform pulse width modulation or pulse frequency modulation based on the output voltage so as to generate the control input that is to be received by the gate driver 73, thereby stabilizing the magnitude (VOUT) of the output voltage. The method 100 depicted in FIG. 1 can be performed on the semiconductor 700 to detect a leakage current of the p-type field effect transistor 71 in the way depicted in FIG. 8. The method 100 depicted in FIG. 1 can be performed on the semiconductor 700 to detect a leakage current of the n-type field effect transistor 72 in the way depicted in FIG. 9.

In accordance with some embodiments of the present disclosure, a semiconductor chip is to be powered by a first supply voltage and a second supply voltage. A magnitude of the first supply voltage is larger than a magnitude of the second supply voltage. The semiconductor chip includes a p-type field effect transistor and a gate driver. The p-type field effect transistor has a gate electrode, a first source/drain region and a second source/drain region, where the first source/drain region is to receive the first supply voltage. The gate driver is connected to the gate electrode of the p-type field effect transistor, and is configured to generate a gate drive signal for receipt by the gate electrode of the p-type field effect transistor, where the gate drive signal switches between a high voltage level and a low voltage level, the low voltage level corresponds to conduction of the p-type field effect transistor and is smaller than the magnitude of the first supply voltage, and the high voltage level corresponds to non-conduction of the p-type field effect transistor and is larger than the magnitude of the first supply voltage.

In accordance with some embodiments of the present disclosure, the semiconductor chip is operable in a test mode. The semiconductor chip is further operable in a normal mode, in which the high voltage level is equal to the magnitude of the first supply voltage.

In accordance with some embodiments of the present disclosure, in the normal mode, the low voltage level is equal to the magnitude of the second supply voltage. In the test mode, the low voltage level is smaller than the magnitude of the second supply voltage.

In accordance with some embodiments of the present disclosure, the semiconductor chip further includes a power supply. The power supply is connected to the gate driver, and is configured to supply a high supply voltage and a low supply voltage to power the gate driver. In the normal mode, a magnitude of the high supply voltage is equal to the magnitude of the first supply voltage, and a magnitude of the low supply voltage is equal to the magnitude of the second supply voltage. In the test mode, the magnitude of the high supply voltage is larger than the magnitude of the first supply voltage, and the magnitude of the low supply voltage is smaller than the magnitude of the second supply voltage.

In accordance with some embodiments of the present disclosure, the gate driver is to be connected to a power source that is configured to provide the first supply voltage, the second supply voltage, a third supply voltage and a fourth supply voltage, where a magnitude of the third supply voltage is larger than the magnitude of the first supply voltage, and a magnitude of the fourth supply voltage is smaller than the magnitude of the second supply voltage. In the normal mode, the gate driver receives the first supply voltage and the second supply voltage from the power source. In the test mode, the gate driver receives the third supply voltage and the fourth supply voltage from the power source.

In accordance with some embodiments of the present disclosure, a difference between the high voltage level and the magnitude of the first supply voltage falls within a range of from 0.2×Vt to 1×Vt, where Vt denotes an absolute value of a threshold voltage of the p-type field effect transistor.

In accordance with some embodiments of the present disclosure, a difference between the high voltage level and the magnitude of the first supply voltage falls within a range of from 0.2×Vt to 2×Vt, where Vt denotes an absolute value of a threshold voltage of the p-type field effect transistor.

In accordance with some embodiments of the present disclosure, a difference between the high voltage level and the magnitude of the first supply voltage falls within a range of from 0.2×Vt to 3×Vt, where Vt denotes an absolute value of a threshold voltage of the p-type field effect transistor.

In accordance with some embodiments of the present disclosure, a difference between the high voltage level and the magnitude of the first supply voltage falls within a range of from 0.2×Vt to 4×Vt, where Vt denotes an absolute value of a threshold voltage of the p-type field effect transistor.

In accordance with some embodiments of the present disclosure, a difference between the high voltage level and the magnitude of the first supply voltage falls within a range of from 0.2×Vt to 5×Vt, where Vt denotes an absolute value of a threshold voltage of the p-type field effect transistor.

In accordance with some embodiments of the present disclosure, the gate driver further configured to supply the first supply voltage to the gate electrode of the p-type field effect transistor, wherein a difference between the high voltage level and the magnitude of the first supply voltage reduces a magnitude of a leakage current of the p-type field effect transistor by at least ten times.

In accordance with some embodiments of the present disclosure, a semiconductor chip is to be powered by a first supply voltage and a second supply voltage. A magnitude of the first supply voltage is larger than a magnitude of the second supply voltage. The semiconductor chip includes an n-type field effect transistor and a gate driver. The n-type field effect transistor has a gate electrode, a first source/drain region and a second source/drain region, where the first source/drain region is to receive the second supply voltage. The gate driver is connected to the gate electrode of the n-type field effect transistor, and is configured to generate a gate drive signal for receipt by the gate electrode of the n-type field effect transistor, where the gate drive signal switches between a high voltage level and a low voltage level, the low voltage level corresponds to non-conduction of the n-type field effect transistor and is smaller than the magnitude of the second supply voltage, and the high voltage level corresponds to conduction of the n-type field effect transistor and is larger than the magnitude of the second supply voltage.

In accordance with some embodiments of the present disclosure, the semiconductor chip is operable in a test mode. The semiconductor chip is further operable in a normal mode, in which the low voltage level is equal to the magnitude of the second supply voltage.

In accordance with some embodiments of the present disclosure, in the normal mode, the high voltage level is equal to the magnitude of the first supply voltage. In the test mode, the high voltage level is larger than the magnitude of the first supply voltage.

In accordance with some embodiments of the present disclosure, a difference between the low voltage level and the magnitude of the second supply voltage falls within a range of from 0.2×Vt to 1×Vt, where Vt denotes a magnitude of a threshold voltage of the n-type field effect transistor.

In accordance with some embodiments of the present disclosure, the gate driver further configured to supply the second supply voltage to the gate electrode of the n-type field effect transistor, wherein a difference between the low voltage level and the magnitude of the second supply voltage reduces a magnitude of a leakage current of the n-type field effect transistor by at least ten times.

In accordance with some embodiments of the present disclosure, a method is for testing a semiconductor chip that includes a field effect transistor, and includes: supplying a first voltage to a first source/drain region of the field effect transistor; supplying a second voltage to a gate electrode of the field effect transistor so as to cause the field effect transistor to not conduct; supplying a third voltage to a second source/drain region of the field effect transistor; and measuring a magnitude of a leakage current of the field effect transistor. A magnitude difference between the second voltage and the third voltage is larger than a magnitude difference between the first voltage and the third voltage.

In accordance with some embodiments of the present disclosure, the field effect transistor has a p-type conductivity. A magnitude of the first voltage is larger than a magnitude of the third voltage. A magnitude of the second voltage is larger than the magnitude of the first voltage.

In accordance with some embodiments of the present disclosure, the field effect transistor has an n-type conductivity. A magnitude of the first voltage is smaller than a magnitude of the third voltage. A magnitude of the second voltage is smaller than the magnitude of the first voltage.

In accordance with some embodiments of the present disclosure, a magnitude difference between the first voltage and the second voltage falls within a range of from 0.2×Vt to 1×Vt, where Vt denotes an absolute value of a threshold voltage of the field effect transistor.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor chip to be powered by a first supply voltage and a second supply voltage, a magnitude of the first supply voltage being larger than a magnitude of the second supply voltage, the semiconductor chip comprising:
a p-type field effect transistor having a gate electrode, a first source/drain region and a second source/drain region, where the first source/drain region is to receive the first supply voltage; and
a gate driver connected to the gate electrode of the p-type field effect transistor, and configured to generate a gate drive signal for receipt by the gate electrode of the p-type field effect transistor, where the gate drive signal switches between a high voltage level and a low voltage level, the low voltage level corresponds to conduction of the p-type field effect transistor and is smaller than the magnitude of the first supply voltage, and the high voltage level corresponds to non-conduction of the p-type field effect transistor and is larger than the magnitude of the first supply voltage.

2. The semiconductor chip according to claim 1, wherein:
the semiconductor chip is operable in a test mode; and
the semiconductor chip is further operable in a normal mode, in which the high voltage level is equal to the magnitude of the first supply voltage.

3. The semiconductor chip according to claim 2, wherein:
in the normal mode, the low voltage level is equal to the magnitude of the second supply voltage; and
in the test mode, the low voltage level is smaller than the magnitude of the second supply voltage.

4. The semiconductor chip according to claim 3, further comprising:
a power supply connected to the gate driver, and configured to supply a high supply voltage and a low supply voltage to power the gate driver;
wherein, in the normal mode, a magnitude of the high supply voltage is equal to the magnitude of the first supply voltage, and a magnitude of the low supply voltage is equal to the magnitude of the second supply voltage; and
wherein, in the test mode, the magnitude of the high supply voltage is larger than the magnitude of the first supply voltage, and the magnitude of the low supply voltage is smaller than the magnitude of the second supply voltage.

5. The semiconductor chip according to claim 3, wherein:
the gate driver is to be connected to a power source that is configured to provide the first supply voltage, the second supply voltage, a third supply voltage and a fourth supply voltage, where a magnitude of the third supply voltage is larger than the magnitude of the first supply voltage, and a magnitude of the fourth supply voltage is smaller than the magnitude of the second supply voltage;
in the normal mode, the gate driver receives the first supply voltage and the second supply voltage from the power source; and
in the test mode, the gate driver receives the third supply voltage and the fourth supply voltage from the power source.

6. The semiconductor chip according to claim 1, wherein:
a difference between the high voltage level and the magnitude of the first supply voltage falls within a range of from 0.2×Vt to 1×Vt, where Vt denotes an absolute value of a threshold voltage of the p-type field effect transistor.

7. The semiconductor chip according to claim 1, wherein:
a difference between the high voltage level and the magnitude of the first supply voltage falls within a range of from 0.2×Vt to 2×Vt, where Vt denotes an absolute value of a threshold voltage of the p-type field effect transistor.

8. The semiconductor chip according to claim 1, wherein:
a difference between the high voltage level and the magnitude of the first supply voltage falls within a range of from 0.2×Vt to 3×Vt, where Vt denotes an absolute value of a threshold voltage of the p-type field effect transistor.

9. The semiconductor chip according to claim 1, wherein:
a difference between the high voltage level and the magnitude of the first supply voltage falls within a range of from 0.2×Vt to 4×Vt, where Vt denotes an absolute value of a threshold voltage of the p-type field effect transistor.

10. The semiconductor chip according to claim 1, wherein:
a difference between the high voltage level and the magnitude of the first supply voltage falls within a range of from 0.2×Vt to 5×Vt, where Vt denotes an absolute value of a threshold voltage of the p-type field effect transistor.

11. The semiconductor chip according to claim 1, wherein:
the gate driver is further configured to supply the first supply voltage to the gate electrode of the p-type field effect transistor, wherein a difference between the high voltage level and the magnitude of the first supply voltage reduces a magnitude of a leakage current of the p-type field effect transistor by at least ten times.

12. A semiconductor chip to be powered by a first supply voltage and a second supply voltage, a magnitude of the first supply voltage being larger than a magnitude of the second supply voltage, the semiconductor chip comprising:
an n-type field effect transistor having a gate electrode, a first source/drain region and a second source/drain region, where the first source/drain region is to receive the second supply voltage; and
a gate driver connected to the gate electrode of the n-type field effect transistor, and configured to generate a gate drive signal for receipt by the gate electrode of the n-type field effect transistor, where the gate drive signal switches between a high voltage level and a low voltage level, the low voltage level corresponds to non-conduction of the n-type field effect transistor and is smaller than the magnitude of the second supply voltage, and the high voltage level corresponds to conduction of the n-type field effect transistor and is larger than the magnitude of the second supply voltage.

13. The semiconductor chip according to claim 12, wherein:
the semiconductor chip is operable in a test mode; and
the semiconductor chip is further operable in a normal mode, in which the low voltage level is equal to the magnitude of the second supply voltage.

14. The semiconductor chip according to claim 13, wherein:
in the normal mode, the high voltage level is equal to the magnitude of the first supply voltage; and
in the test mode, the high voltage level is larger than the magnitude of the first supply voltage.

15. The semiconductor chip according to claim 12, wherein:
a difference between the low voltage level and the magnitude of the second supply voltage falls within a range of from 0.2×Vt to 1×Vt, where Vt denotes a magnitude of a threshold voltage of the n-type field effect transistor.

16. The semiconductor chip according to claim 12, wherein:
the gate driver is further configured to supply the second supply voltage to the gate electrode of the n-type field effect transistor, wherein a difference between the low voltage level and the magnitude of the second supply voltage reduces a magnitude of a leakage current of the n-type field effect transistor by at least ten times.

17. A method for testing a semiconductor chip that includes a field effect transistor, comprising:
supplying a first voltage to a first source/drain region of the field effect transistor;
supplying a second voltage to a gate electrode of the field effect transistor so as to cause the field effect transistor to not conduct;
supplying a third voltage to a second source/drain region of the field effect transistor; and
measuring a magnitude of a leakage current of the field effect transistor;
wherein a magnitude difference between the second voltage and the third voltage is larger than a magnitude difference between the first voltage and the third voltage.

18. The method according to claim 17, the field effect transistor having a p-type conductivity, wherein:
a magnitude of the first voltage is larger than a magnitude of the third voltage; and
a magnitude of the second voltage is larger than the magnitude of the first voltage.

19. The method according to claim 17, the field effect transistor having an n-type conductivity, wherein:
a magnitude of the first voltage is smaller than a magnitude of the third voltage; and
a magnitude of the second voltage is smaller than the magnitude of the first voltage.

20. The method according to claim 17, wherein:
a magnitude difference between the first voltage and the second voltage falls within a range of from 0.2×Vt to 1×Vt, where Vt denotes an absolute value of a threshold voltage of the field effect transistor.
